(19) United States
(12) Patent Application Publication
(10) Pub. No.: US 2005/0218801 A1
(43) Pub. Date: Oct. 6, 2005

(54) Replaceable light emitting diode package assembly

(76) Inventors: Schang-Jing Hon, Pa Te City (TW); Mu-Jen Lai, Chungli City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/813,088

(22) Filed: Mar. 31, 2004

(51) Int. Cl. H01L 33/00; H01J 1/62

(52) U.S. Cl. 313/512

(57) ABSTRACT

A replaceable light emitting diode (LED) package assembly has a separate structure and manufacturing process of the LED package. The LED die and a set of fluorescent material are located on a substrate. The fluorescent material device can be arranged selectively to match a required emission color according to the characteristic of wavelength of the LED die and not only is blended precisely to provide the required color but also reduces the rate of defects for the individual components of the assembly.

### BACKGROUND OF THE INVENTION

1. Field of the Invention

The present invention relates to a replaceable light emitting diode package assembly, which discloses a separate structure and manufacturing process for a substrate with at least a LED die located and a set of fluorescent material respectively for achieving high yielding ratio.

2. Description of Related Art

FIG. 1 shows a cross-sectional view of a prior art surface mounted (SMD) light emitting diode (LED) device, which comprises a ring-shaped plastic reflective cup 13 on a substrate 11 and an LED die 14 mounted thereon. The LED die 14 connects with the substrate 11 electrically by a metal conducting leadframe 12. The reflective cup 13 focuses and reflects the light from LED. An epoxy resin coating 15 encapsulates the LED die 14, and a UV (ultraviolet ray) epoxy resin layer 16 is coated on the epoxy resin coating 15 for binding a hemisphere-shaped plastic rubber 17 thereon. Nevertheless, the manufacturing process of the SMD LED device in the prior art produces defects on account of the differences in physical characteristics of the used materials. An example is the displacement occurred due to the different layer materials with different coefficient of expansion in the structure of LED, and Taiwan Patent No. 560697 discloses a structure of a SMD LED to correct the fault.

FIG. 2 shows another prior art SMD LED, in which a packaging glue 24 is cast on a printed circuit board (PCB) 21 directly and an extra colloid is adhered thereon as well, so that the packaging glue 24 will not fall off. Alternatively, a metal reflective cup 23 is employed to reflect and focus the light from the LED die 22 located therein.

In addition to the description of the SMD LED in the previous description, yet another kind of lead-type LED structure exists, such as that disclosed by Taiwan Patent No. 564535 and shown in FIG. 3, which refers to a carrier 30 including a pair of leads 39 to connect with other components or the circuit board of LED. In the space of a cavity 36, an LED die 32 is adhered on the PCB 33 by a bonding layer 38, and the electrode 37 of LED die 32 is bonded with the electrical terminal of leads 39 by wire 35. Furthermore, the LED die 32 is encapsulated with a fluorescent layer 34 and light-guiding packaging glue 31.

Reference is made to the prior art described in FIGS. 1, 2 and 3 above, in which the packaging glue 24, 31 are formed integrally or assembled with other components outside the LED die respectively and then the fluorescent layer also envelopes the LED die for adjusting the emission color. Although the prior art described in Taiwan Patent No. 552726 provides a solution to the problem for thermal dissipation of LED, color error still occurs due to deviations in the manufacturing process and the materials of the fluorescent layer.

To correct the problem in the prior art, the present invention provides a replaceable light emitting diode package assembly with a fluorescent component set for the good flexibility in the process of fabrication and solve the problem discovered after packaging in the prior art.

### SUMMARY OF THE DISCLOSURE

Broadly speaking, the invention relates to a replaceable light emitting diode package assembly, which discloses the separate manufacturing process of the LED package including a substrate the LED die located and a set of fluorescent material, respectively. The device of fluorescent material can be changed selectively, and economize the use of the fluorescent material, which is changed in accordance with requirement as desired.

The assembly comprises a stand, a reflective cup set upon the stand, at least one LED chip that electronically connect with the stand and a fluorescent component set, which can be transparent and removed from the LED.

### BRIEF DESCRIPTION OF DRAWINGS

The present invention will be readily understood by the following detailed description in conjunction accompanying drawings, in which:

FIG. 1 is a schematic drawing of a surface mounted device LED of the prior art;

FIG. 2 is a schematic drawing of a SMD LED of the prior art;

FIG. 3 is a schematic drawing of a lead-frame LED of the prior art;

FIG. 4 is a schematic drawing of the first present invention embodiment of the replaceable light emitting diode package assembly;

FIG. 5 is a schematic drawing of the second embodiment of the present invention;

FIG. 6 is a schematic drawing of the third embodiment of the present invention;

FIG. 7 is a schematic drawing of the fourth embodiment of the present invention;

FIG. 8 is a schematic drawing of the fifth embodiment of the present invention; and

FIG. 9 is a schematic drawing of the sixth embodiment of the present invention.

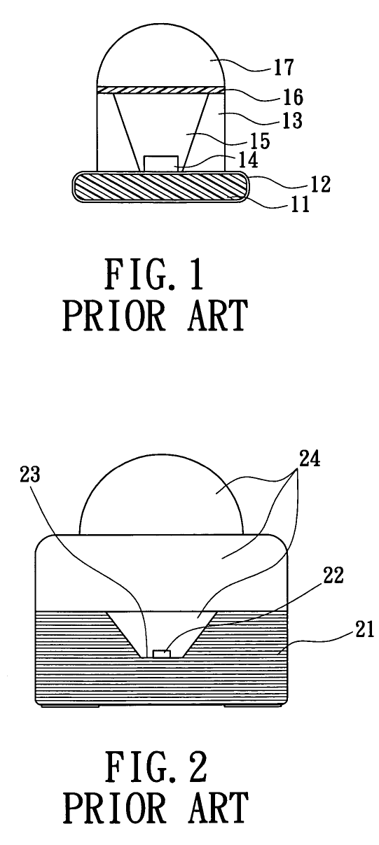

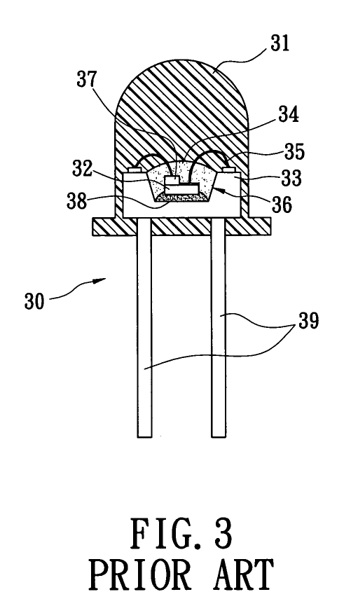

### DETAILED DESCRIPTION OF THE PREFERRED EMBODIMENTS

One aspect of the present invention relates to a technique of combining light emitting diode (LED) components, which includes a replaceable fluorescent unit and an emitting device unit, respectively. The fluorescent unit can be made of fluorescent material or coated with fluorescent material on its surface, thus achieving a separate structure and manufacturing process for a substrate whereon the LED chip located and a set of fluorescent material.

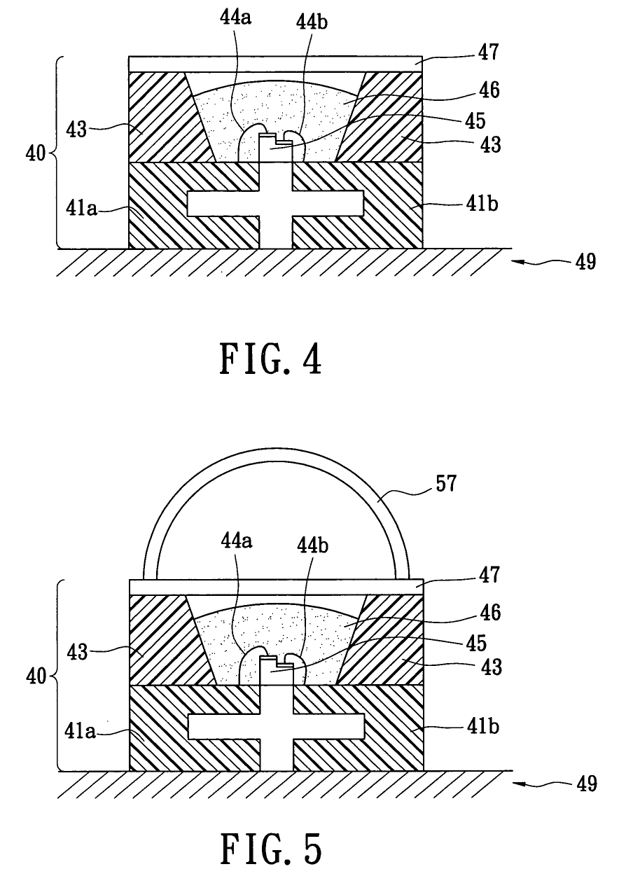

Reference is made to FIG. 4, which is a schematic drawing of the first embodiment of present invention. The combination of the fluorescent unit 47 and the emitting device unit 40, which is a kind of surface mounted type (SMD) LED, is shown. The metal terminal 41a, 41b of LED is constructed on the circuit board 49, and a first terminal 41a and a second terminal 41b are connected with the two electrodes of LED chip 45, respectively. A reflective cup 43 with the function of focus and reflection is installed above the metal terminal, and an LED chip 45 of the emitting device unit 40 is connected with the elements of circuit board by metal reflective cup 43. For instance, the LED chip 45 connects with the anode shown on the first terminal 41a by a first bonding wire 44a, and with cathode shown on the second terminal 41b by a second bonding wire 44b.

As described above, one or more LED chips 45 are embedded firmly using a packaging glue 46 and then covered with the replaceable fluorescent unit 47, the LED chips 45 are separated with fluorescent unit 47 such that a space is present there. In the replaceable light emitting diode package assembly, fluorescent unit 47 is combined with the structure in a removable way such as bonding by glue, welding by RF heating source, or assembling with a tenon structure.

The fluorescent unit 47 is made of transparent material and fluorescent powder material is added on the top face thereof, bottom face thereof or interior of the fluorescent unit 47. The luminosity or color of the LED device can be adjusted by varying the fluorescent powder composition of the fluorescent unit 47. In the case of a white light, the LED chip 45 itself can be a blue light LED, and then collocated with yellow fluorescent unit 47 to blend their emitted light into the white light as required. The chromaticity of the white light is also adjustable in the present invention.

The invention can correct problems by replacing the fluorescent unit 47 if any defect occurs during the manufacturing process, and further achieve thermal dissipation by providing a space between the fluorescent unit 47 and LED chip 45. Additionally, the characteristic of light is also adjusted by setting different fluorescent materials near the LED chip 45.

FIG. 5 is the second embodiment of the invention; like the structure shown in FIG. 4, the package structure of fluorescent unit 57 and emitting device unit 40 are illustrated. The circuit board 49 is a printed circuit board (PCB), and the LED chip 45 connects with the first terminal 41a and the second terminal 41b by the first bonding wire 44a and the second bonding wire 44b, respectively, and electrically connects to the circuit board 49. Further, the reflective cup 43 set above the terminals 41a, 41b, and the LED chip 45 is embedded firmly using a packaging glue 46 and again covered with a replaceable fluorescent unit 57. The LED chip 45 is separated from the fluorescent unit 57 with a replaceable adhesive material to connect to emitting device unit 40.

The fluorescent unit 57 in the current embodiment is a transparent material with hollow hemispheric shape, and the fluorescent materials can be coated on the outer surface, inner surface or doped inside the unit for uniform light emission. The emitted light can be adjusted by adjusting the fluorescent composition of fluorescent unit 47, especially with regard to the color temperature, and the unit is replaced as required.

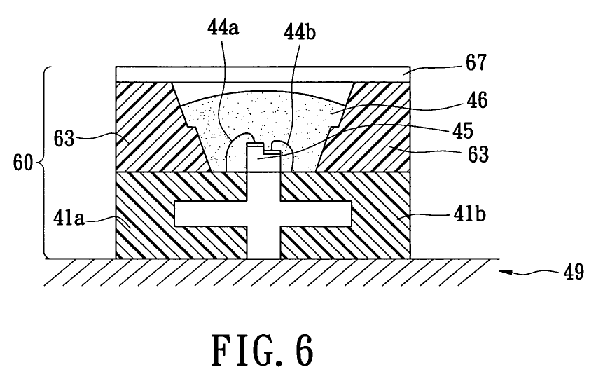

FIG. 6 is a third embodiment of the present invention, which introduces a double-tiered reflective cup 63 for reflecting and focusing the light emitted from LED chip 45. As recited with regard to the first and second embodiments above, the LED chip 45 is set on a first terminal 41a and a second terminal 41b and then connects to the electrodes on the terminals 41a and 41b by a first bonding wire 44a and a second bonding wire 44b. The LED chip 45 is embedded firmly using packaging glue 46, and the emitting device unit 60 is formed with a combination of double tiered reflective cup 63 and metal terminals 41a, 41b. The invention achieves the purpose of combination and replacement by a different manufacturing process of covered replaceable fluorescent unit 67 and emitting device unit 60.

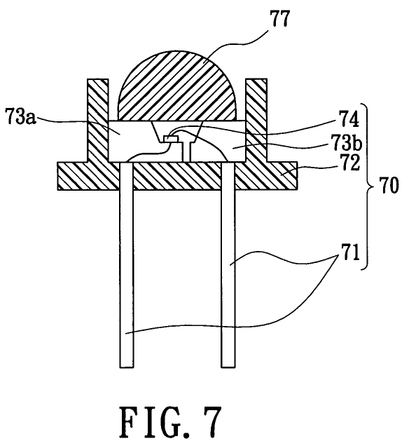

FIG. 7 is a schematic drawing of a fourth embodiment of the present invention. This figure discloses the structure of a lead-type LED, which is a combination of a fluorescent unit 77 and an emitting device unit 70, including other elements and connecting leads 71 as shown in the drawing. The leads 71 are connected with the first terminal 73a and the second terminal 73b, which are the anode and cathode individually, and then the two electrodes (anode, cathode) of LED chip 74 connect to the terminals 73a and 73b by bonding wires, respectively. The LED chip 74 is set on the concave metal cup-shaped structure formed by terminals 73a and 73b for reflecting and focusing the light.

Thus, the first terminal 73a, the second terminal 73b and the LED chip 74 are enveloped by a package 72, also including the terminal electrodes of pins 71 for fastening the structure. Above the LED chip 74 there is a fluorescent unit 77 made of transparent material in, for example but not limited to, a solid or hollow bomb-like shape. The fluorescent unit 77 is connected with the emitting device unit 70 using the replaceable technique of combination The outer or inner surface of the unit is coated with fluorescent material in accordance with the required luminosity and color, furthermore, the fluorescent unit 67 can be fluorescent material itself. The present invention can change the brightness or color as required by adjusting the composition and concentration of material.

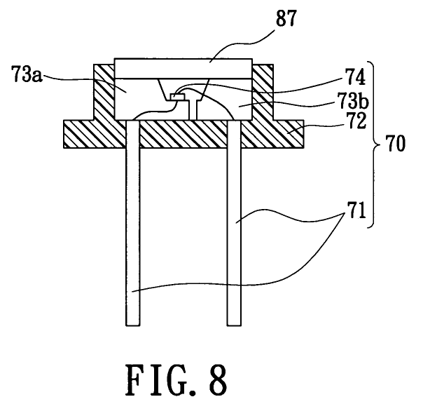

Just as illustrated in FIG. 7, FIG. 8 is the fifth embodiment of the invention showing the combination of fluorescent unit 87 and the emitting device unit 70, combined with the replaceable adhesive material. The hollow or solid fluorescent unit 87 is set on the LED chip 74 and terminals 73a and 73b, which are coated with fluorescent material on the outer or inner surface thereof or doped inside. In addition, the composition can be changed according to needs.

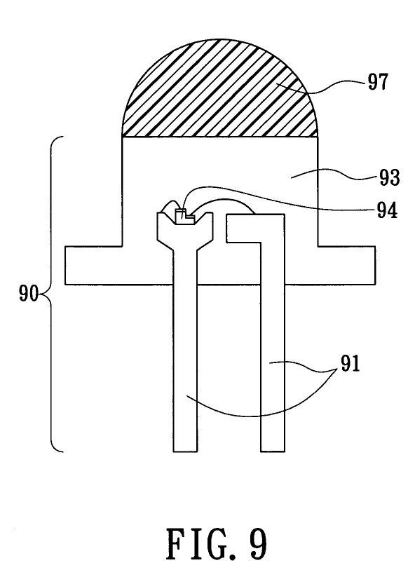

Reference is made to FIG. 9, which shows the sixth embodiment of the invention. The LED chip 94 is set on the terminal formed with the leads 91, which are used as an anode and a cathode, respectively, connected to the LED chip 94 by bonding wires. The emitting device unit 90 comprises the LED chip 94 and a leads 91 enveloped with package 93 and a fluorescent unit 97 is set above the emitting device unit 90 to allow easy replacement.

The many features and advantages of the present invention are apparent from written description above and intended by appended claims to cover all. Further, since numerous modifications and changes will readily occur to those skilled in the art, it is not desired to limit the invention to the exact construction and operation as illustrated and described. Hence, all suitable modifications and equivalents may be resorted to as falling within the scope of the invention.

1. A replaceable LED package assembly, comprising:
a terminal set comprising a first terminal and a second terminal functioning as anode and cathode, respectively;
a reflective cup installed on said terminal set;
at least one light emitting diode (LED) chip installed on said reflective cup and electrically connected with said terminal set; and
a fluorescent unit installed on said LED chip and apart from said LED chip, the fluorescent unit being made of transparent material.

2. The replaceable LED package assembly as recited in claim 1, wherein said reflective cup is made of light-reflecting metal material.

3. The replaceable LED package assembly as recited in claim 1, wherein said fluorescent unit is a fluorescent material.

4. The structure of replaceable LED package as recited in claim 1, wherein said fluorescent unit is coated with fluorescent material on a surface portion thereof.

5. The replaceable LED package assembly as recited in claim 1, wherein said fluorescent unit is either hollow or solid.

6. The replaceable LED package assembly as recited in claim 1, wherein said fluorescent unit is combined with said structure using a replaceable technique of combination.

7. The replaceable LED package assembly as recited in claim 6, wherein said replaceable technique is bonding with glue, welding with an RF heating source, or assembling with tenon structure.

8. The replaceable LED package assembly as recited in claim 1, wherein said LED chip is embedded firmly using a packaging glue.

9. A replaceable LED package assembly, comprising:
an emitting device unit including one or a plurality of LED chips; and
a fluorescent unit made of transparent material and combined with said structure using a replaceable technique of combination.

10. The replaceable LED package assembly as recited in claim 9, wherein said fluorescent unit is made of transparent material.

11. The replaceable LED package assembly as recited in claim 9, wherein said fluorescent unit is a fluorescent material.

12. The replaceable LED package assembly as recited in claim 9, wherein the surface of said fluorescent unit is coated with fluorescent material.

13. The replaceable LED package assembly as recited in claim 9, wherein said fluorescent unit is hollow or solid.

14. The replaceable LED package assembly as recited in claim 9, wherein said LED chip connects with a circuit outside said structure of the replaceable LED package.

15. The replaceable LED package assembly as recited in claim 9, wherein said replaceable technique is bonding with glue, welding with an RF heating source, or assembling with tenon structure.
